(19) United States
(12) Patent Application Publication
(10) Pub. No.: US 2007/0253264 A1
(43) Pub. Date: Nov. 1, 2007

(54) Integrated Semiconductor Memory with a Test Function and Method for Testing an Integrated Semiconductor Memory

(76) Inventors: Manfred Proell, Dorfen (DE); Juan Ocon, Muenchen (DE); Frank Ertl, Muenchen (DE); Stephan Schroeder, Muenchen (DE)

Correspondence Address: SLATER & MATSIL, L.L.P., 17950 PRESTON ROAD, SUITE 1000, DALLAS, TX, 75252, US

(21) Appl. No.: 11/740,768

(22) Filed: Apr. 26, 2007

(30) Foreign Application Priority Data
Apr. 26, 2006 (DE) 10 2006 019 507.8

(51) Int. Cl. G11C 29/00; G11C 7/00

(52) U.S. Cl. 365/201

(57) ABSTRACT

An integrated semiconductor memory with a test function comprises a bit line pair having a first end and a second end. A voltage generation circuit having a first connection and a second connection is coupled to the first end of the bit line pair. A plurality of memory cells are connected to a bit line of the bit line pair between the first end and second end of the bit line pair. A controllable switch is connected between the second end of the bit line pair.

This application claims priority to German Patent Application 10 2006 019 507.8, which was filed Apr. 26, 2006 and is incorporated herein by reference.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows an exemplary embodiment of an integrated semiconductor memory;

FIG. 2 shows an exemplary embodiment of a memory cell array of an integrated semiconductor memory;

FIG. 3 shows an exemplary time diagram of a current in an integrated semiconductor memory;

FIG. 4 shows an exemplary time diagram of currents and voltages in an integrated semiconductor memory; and

FIG. 5 shows another exemplary embodiment of an integrated semiconductor memory.

### DETAILED DESCRIPTION OF ILLUSTRATIVE EMBODIMENTS

A memory array of a semiconductor memory, in particular a Dynamic Random Access Memory (DRAM), comprises memory cells which are arranged in rows and columns. The individual memory cells are accessed using word lines and bit lines. During memory access, a word line is first of all activated. As a result, the memory cells which are arranged in a row are each conductively connected to a bit line. A charge which is stored in the memory cell results in the bit line voltage being displaced. A sense amplifier which compares this voltage with a voltage on a complementary bit line and then amplifies it is situated at the end of the bit line.

Since the process of producing semiconductor memories is optimized in terms of cost, it is desirable to produce the bit lines in the semiconductor memory in such a manner that they have the smallest possible width. In this case, technology-induced production faults may occur. For example, bit line sections which have a high impedance and have an adverse effect on, inter alia, the performance of the semiconductor memory and its reliability may be produced during fabrication.

During continuous operation of the semiconductor memory, in particular, a bit line section which has a high impedance may also take on an even higher impedance or may completely lose conductivity, for example, as a result of electromigration. In order to be able to sort out semiconductor memories having such defective bit lines before being used or sold, an attempt is made to identify the defective semiconductor memories by means of tests at the manufacturer's premises.

Reliability problems with high-impedance very thin bit lines may be detected, for example, by stressing the bit lines using high currents. In this case, the semiconductor memory is operated at elevated temperature and excessive internal voltages in order to accelerate impairment of the conductivity or destruction of the bit line. As a result, a defect in the semiconductor memory occurs while it is still with the manufacturer rather than with the user.

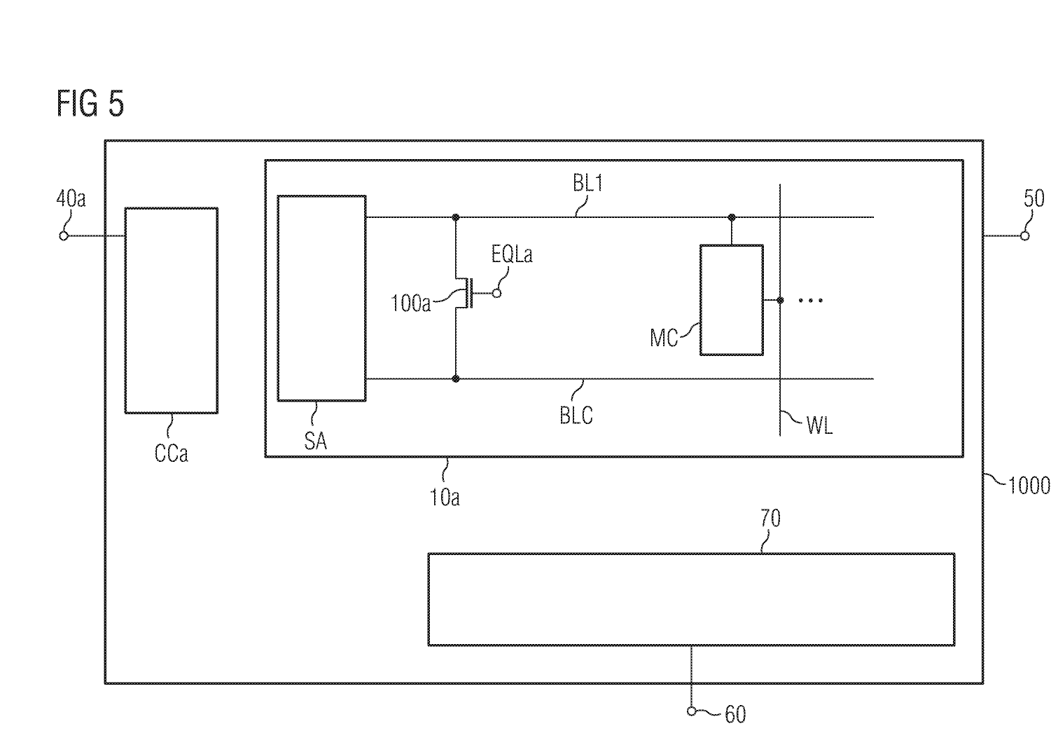

FIG. 5 shows an exemplary embodiment of an integrated semiconductor memory 1000. The latter comprises a control circuit CCa having an input 40a, an address buffer 70 having an address input 60, and a memory cell array 10a. Data can be read from the memory cell array 10a or written to the memory cell array 10a via a data connection 50.

The memory cell array 10a has a sense amplifier SA, bit lines BL1, BLC which are connected to the latter, and a precharge transistor 100a. At least one memory cell MC which can be driven using a word line WL is connected to a bit line BLI.

In order to read a memory cell, the precharge transistor 100a is turned on using a signal at its control input EQLa, with the result that a standard starting potential is produced on the bit lines BL1 and BLC. On the basis of signals at the input 40a of the control circuit CCa and at the address input 60, the memory cell MC is driven using the word line WL in such a manner that a charge stored in the memory cell changes the potential on the bit line BL1. The resulting potential difference between the potentials on the bit lines BL1 and BLC is amplified by the sense amplifier SA, with the result that a first line potential is established on one of the bit lines BL1, BLC and a second line potential is established on the other bit line. The precharge transistor 100a is connected to the bit lines BL1, BLC between the sense amplifier SA and the memory cells MC, that is to say directly at the sense amplifier SA.

FIG. 4 shows a time diagram for voltage and current during operation and when testing a semiconductor memory, for example, the semiconductor memory 1000 shown in FIG. 5. The voltage profile VN represents the profile of the voltage at a point on a bit line during normal operation of the semiconductor memory. The bit line has resistance properties and capacitive properties. As the voltage VN increases, at the time t1, from a starting voltage to the voltage VBLH, a charge reversal operation, which becomes noticeable in the current IBL, is carried out on the bit line. As the voltage VN falls from the starting voltage, at the time t2, to a reference voltage GND, the charge reversal current IBL is produced on the bit line with a changed current direction on account of the differently directed charge reversal operation.

During test operation, which is also referred to as burn-in, the voltages VBI used are higher. At the time t1, the voltage VBI increases from a starting voltage, which is higher than the starting voltage during normal operation, to the voltage VBLH BI. Since the voltage difference is greater for the voltage VBI, this also results in a temporarily higher current flow IBL BI on the bit line. A similar situation applies to the voltage drop of the voltage VBI at the time t3. A current peak of the current IBL BI with a reversed current direction results in this case too.

As is evident from FIG. 4, only a dynamic current flows over the bit line during charge reversal. On account of the higher voltage during test operation, the dynamic currents on the bit line are increased in comparison with normal operation but the frequency of the charge reversal operations is reduced in comparison with normal operation.

With this test method, the bit lines in the semiconductor memory are loaded or stressed only with the dynamic charge reversal currents. Bit lines having weak points and an increased probability of failure are thus not reliably destroyed under certain circumstances during testing and thus cannot be detected.

In one embodiment, an integrated semiconductor memory with a test function comprises a first bit line and a second bit line, a voltage generation circuit, a plurality of memory cells and a circuit unit. The first and second bit lines each have a first end and a second end. The voltage generation circuit has a first connection, at which a first line potential can be generated and which is coupled to the first end of the first bit line, and a second connection, at which a second line potential can be generated and which is coupled to the first end of the second bit line. The memory cells are connected to the first bit line between the first and second ends of the first bit line. The circuit unit comprises a control input for supplying a first control signal and a first controllable switch which is connected between the second end of the first bit line and the second end of the second bit line. A control connection of the first controllable switch is coupled to the control input.

The voltage generation circuit that is connected to one end of the bit line pair formed from the first and second bit lines can be used to generate voltages on the bit lines, as a result of which a potential difference between the voltages on the first and second bit lines is produced. Closing the switch in the circuit unit, which is connected between the bit lines at the other end of the bit line pair, makes it possible to establish a static current over the bit lines on account of the nonreactive resistance of the bit lines. Since the memory cells are connected to the first bit line between the voltage generation circuit and the switch, the current flows over the entire area of the bit lines which is used during operation.

In contrast to the dynamic charge reversal currents, this static current permanently loads the bit lines. Bit lines having weak points can thus be caused to fail or be destroyed as early as during testing. It is thus possible to identify defective bit lines in a more reliable manner.

In another embodiment, the integrated semiconductor memory comprises a control circuit having an input for selecting an operating mode from a first operating mode and a second operating mode of the integrated semiconductor memory. The first line potential is generated on the first bit line and the second line potential is generated on the second bit line in the first and second operating modes when reading one of the plurality of memory cells. In this case, the control circuit turns off the first switch in the circuit unit in the first operating mode and turns it on in the second operating mode.

The practice of generating a static current is usually desired only for testing the semiconductor memory. During normal operation of the semiconductor memory, the switch is open when reading a memory cell, with the result that the bit lines are not connected to one another in a low-impedance manner. The first operating mode therefore corresponds to normal operation of the semiconductor memory, for example, while the second operating mode corresponds to test operation of the semiconductor memory.

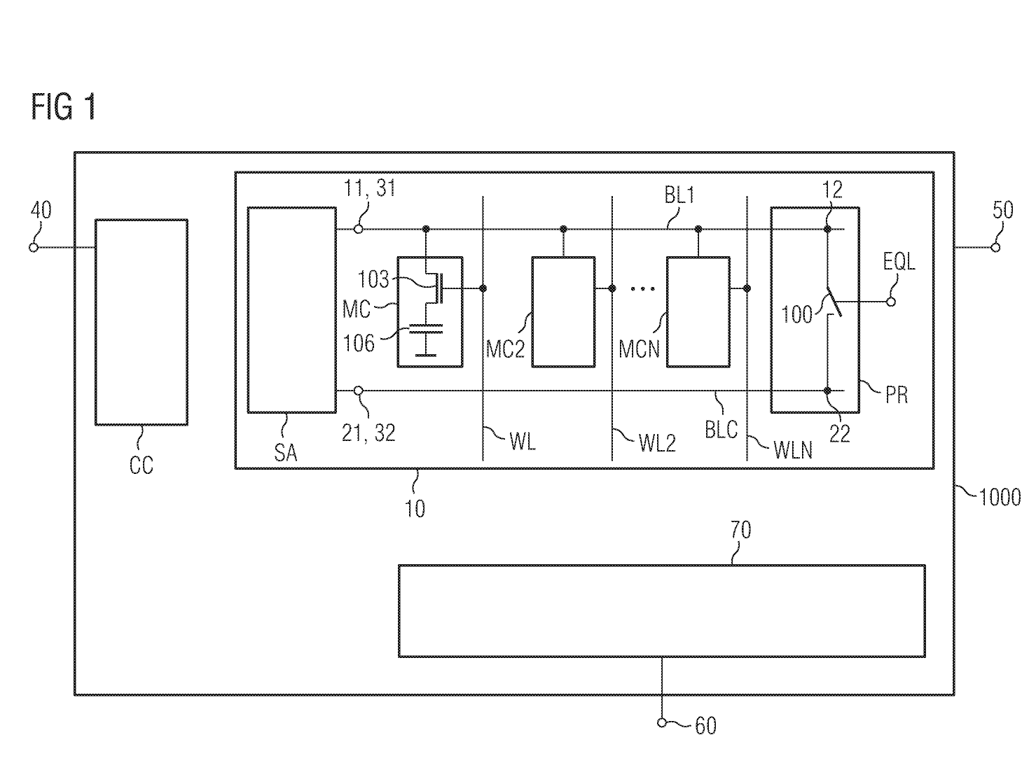

FIG. 1 shows an exemplary embodiment of an integrated semiconductor memory 1000. The latter comprises a control circuit CC having an input 40, an address buffer 70 having an address input 60, a data connection 50, and a memory cell array 10. The memory cell array 10 has a voltage generation circuit SA having a first connection 31 and a second connection 32, which are respectively coupled to the first end 11 of a first bit line BL1 and to the first end 21 of a second bit line BLC. A controllable switch 100 in a circuit unit PR is connected between a second end 12 of the first bit line BL1 and a second end 22 of the second bit line BLC. The switch 100 is coupled to a control input EQL. A plurality of memory cells MC, MC2, MCN are connected to the first bit line BL1 between the first end and the second end 12 of the first bit line BL1. The memory cells MC, MC2, MCN are also coupled to word lines WL, WL2, WLN. The structure of a memory cell MC is represented, for example, by a control transistor 103 and a storage capacitor 106. A value or a storage state of the memory cell MC can be stored in the storage capacitor 106 using a charge. The memory cell MC is driven using the control transistor 103 whose control input is connected to the word line WL.

The voltage generation circuit SA is in the form of a sense amplifier, for example. The circuit unit PR is also in the form of a precharge circuit, for example.

In contrast to an embodiment of a semiconductor memory, as is shown in FIG. 5, for example, the memory cells MC, MC2, MCN are connected to the first bit line BL1 between the sense amplifier SA and the precharge circuit PR. In the control circuit CC, the input 40 can be used to select an operating mode, for example an operating mode for the purpose of testing and an operating mode for normal operation.

In the operating mode for the purpose of testing, a precharge potential that usually corresponds to a mean value of a high bit line potential and a low bit line potential is established, for example, on the first bit line BL1 and on the second bit line BLC. Driving a memory cell MC using a word line WL results in a potential shift on the first bit line BL1 on account of the charge stored in the memory cell MC. A slight potential difference between the potentials of the bit lines BL1 and BLC is thus produced. This potential difference is detected by the sense amplifier SA and is amplified in such a manner that one of the bit lines BL1, BLC is at the high bit line potential, while the other bit line is at the low bit line potential.

The controllable switch 100 is closed by driving it. This results in a low-impedance connection of the two bit lines BL1, BLC. The electrical resistance of the bit lines BL1, BLC results in a current flowing from the first connection 31 of the sense amplifier SA to the second connection 32 of the sense amplifier SA via the first bit line BL1, the switch 100 and the second bit line BLC. This produces a static current flow over the bit lines BL1, BLC, the polarity or direction of said current flow depending on whether the amplified potential difference is positive or negative. The direction of current flow is thus influenced by the charge or information stored in the memory cell MC.

In comparison with dynamic charge reversal currents during normal operation of the semiconductor memory or in the case of conventional semiconductor memories, loading the bit lines BL1, BLC with a static current is more efficient since it is possible to load or stress the bit lines for relatively short periods of time for test operation. Defective bit lines can thus be caused to fail early, as a result of which the probability of a semiconductor memory failing during use, that is to say when it is with a customer, is reduced.

A word line WL, WL2, WLN and thus a memory cell MC, MC2, MCN are driven on the basis of an address signal at the address input 60 of the address buffer 70. In this case, it is irrelevant, for test operation, which of the memory cells MC, MC2, MCN connected to the first bit line BL1 is driven since the static current flows over the entire area of the bit lines BL1, BLC which is used during operation.

After the bit lines BL1, BLC have been loaded or stressed with the static current, a further operating mode can check whether the function of the bit lines BL1, BLC and thus of the memory cell array 10 is ensured. The functionality can be checked, for example, by means of write and read access to one of the memory cells MC, MC2, MCN connected to the bit line BL1 during normal operation. To this end, a first data item is applied to the data connection 50 and is read into one of the memory cells. A second data word is generated at the data connection 50 by reading the storage state of the memory cell which has just been written to. If the first and second data items are different, it can be assumed that one of the bit lines is damaged.

However, if the memory cell can be written to and read without errors, the bit lines BL1, BLC are not damaged by the static current during test operation, which indicates a permanently functional bit line pair.

The potential difference between the potentials of the bit lines BL1, BLC is usually higher during test operation than during a read process during normal operation. Since this also results in a higher current over the bit lines BL1, BLC, defective bit lines are destroyed with a higher degree of probability.

In another embodiment, a coupling circuit is connected between the first ends of the first and second bit lines and the connections of the voltage generation circuit, the coupling circuit having a selection input and being designed to connect the first ends of the first and second bit lines to the connections of the voltage generation circuit on the basis of a second control signal at the selection input.

The coupling circuit may comprise a first controllable switch and a second controllable switch, the first controllable switch being connected between the first connection of the voltage generation circuit and the first end of the first bit line, and the second controllable switch being connected between the second connection of the voltage generation circuit and the first end of the second bit line. Control connections of these controllable switches are coupled to the selection input.

The coupling circuit can be used to electrically disconnect the voltage generation circuit from the bit lines by turning off the switches using the second control signal at the selection input, for example. As a result, the voltage generation circuit can alternatively also be used for other bit line pairs which are likewise connected to the voltage generation circuit via controllable switches. In this case, only one bit line pair should ever be electrically connected to the voltage generation circuit at the same time.

In another embodiment, the circuit unit is in the form of a precharge circuit for feeding a precharge potential to the first and second bit lines. In this case, the precharge potential is between the first and second line potentials.

The precharge circuit may comprise a second controllable switch which couples the second end of the first bit line to a supply connection for supplying the precharge potential, and a third controllable switch which couples the second end of the second bit line to the supply connection. In this case, control connections of the second and third controllable switches are coupled to the control input.

This makes it possible to precharge the bit line to an essentially standard potential, the precharge potential, before a memory cell is driven in order to be read. In this case, the precharge potential is usually supplied in a high-impedance manner. The controllable switches in the circuit unit or in the precharge circuit are jointly driven using the first control signal at the control input. If the switches are turned on while there is a voltage difference between the bit lines, the current essentially flows over the bit lines via the first controllable switch, in particular if the two other controllable switches in the precharge circuit have the same electrical resistance when turned on. This is because, in this case, a potential which is between the potential on the first bit line and the potential on the second bit line is established at a connecting node of the two switches, the connecting node being coupled to the supply connection. This usually also corresponds to the precharge potential which can be supplied via this connecting node.

The controllable switches in the circuit unit and in the coupling circuit can each be in the form of a transistor. Field effect transistors, for example, can be used for this purpose.

In another embodiment, at least one of the plurality of memory cells is designed to generate a potential difference between a potential on the first bit line and a potential on the second bit line when driven using a word line. The voltage generation circuit can be designed to amplify this potential difference.

Driving a memory cell for the purpose of reading usually connects the memory cell to the first bit line in a low-impedance manner, with the result that the charge stored in the memory cell gives rise to a slight potential shift on the first bit line. This results in a potential difference between the potential on the first bit line and the potential on the second bit line.

If the voltage generation circuit is in the form of a sense amplifier, the sense amplifier, which usually operates in accordance with the principle of a differential amplifier, can detect this potential difference and returns it to the bit lines in amplified form.

For example, the sense amplifier generates the first and second line potentials on the first and second bit lines on the basis of the potential difference in order to amplify the potential difference.

If the initial potential difference was positive, for example, by virtue of a stored logic one, the sense amplifier usually connects the first bit line to a high bit line potential and connects the second bit line to a low bit line potential. This produces an amplified positive potential difference between the bit lines. If a logic zero is stored in the memory cell, the initial potential difference is usually negative. The sense amplifier then applies the low bit line potential to the first bit line and the high bit line potential to the second bit line. This results in a negative amplified potential difference between the bit lines.

During test operation of the semiconductor memory, this can be used to influence the direction of flow of the static current over the bit line when the bit lines are connected in a low-impedance manner by the controllable switch in the circuit unit.

In addition, the voltage generation circuit can be designed to generate a third line potential at the first connection and a fourth line potential at the second connection, a potential difference between the third and fourth line potentials being greater than a potential difference between the first and second line potentials. This makes it possible to generate a higher static current over the bit line during test operation in order to be able to determine bit lines which are susceptible to faults after a relatively short test time.

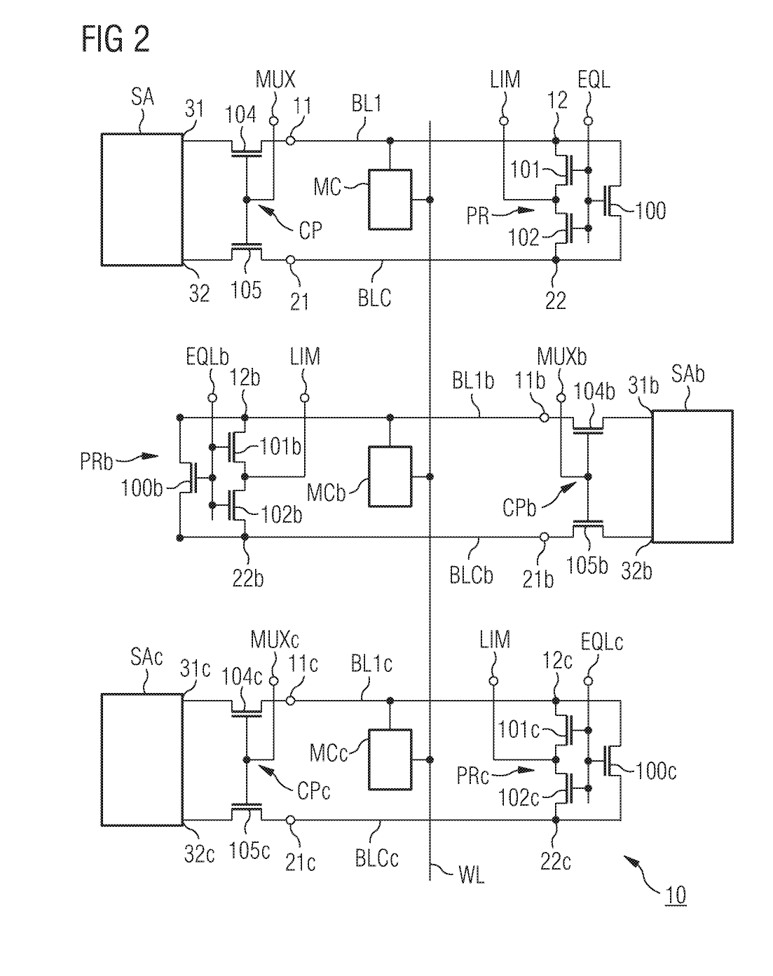

FIG. 2 shows an exemplary embodiment of a memory cell array 10 which can be used in an integrated semiconductor memory. Functionally and operatively identical components have the same reference symbols in this case. The memory cell array 10 comprises a plurality of bit line pairs having the bit lines BL1 and BLC, BL1b and BLCb and BL1c and BLCc. For reasons of clarity, only one memory cell MC, MCb, MCc is respectively illustrated for a bit line pair, said memory cells being able to be driven using a common word line WL. A coupling circuit CP having transistors 104 and 105 whose control connections are coupled to a selection input MUX is connected between the first ends 11, 21 of the first and second bit lines BL1, BLC and the connections 31, 32 of the sense amplifier SA. The precharge circuit PR is connected between the second ends 12, 22 of the first and second bit lines BL1, BLC. The precharge circuit comprises a transistor 100 as a controllable switch and a series circuit comprising two transistors 101, 102 whose connecting node is connected to a potential input LIM. Control connections of the transistors 100, 101, 102 are coupled to the control input EQL.

A coupling circuit CPb having transistors 104b, 105b whose control connections are coupled to a selection input MUXb is connected between the first ends 11b, 21b of the bit line pair BL1b, BLCb and connections 31b, 32b of a second sense amplifier SAb. A precharge circuit PRb which, with the transistors 100b, 100b, 102b, has essentially the same design as the precharge circuit PR is connected between the second ends 12b, 22b of the bit line pair BL1b, BLCb. Control connections of the transistors 100b, 101b, 102b are coupled to a control input EQLb.

A third bit line pair BL1c, BLCc is also connected in a similar manner to the previous bit line pairs. A precharge circuit PRc has transistors 100c, 101c, 102c whose control connections are connected to a control input EQLc. In this case, the precharge circuit PRc is connected between second ends 12c, 22c of the bit line pair BL1c, BLCc. A sense amplifier SAc having the connections 31c, 32c is connected to the other end 11c, 21c of the bit line pair BL1c, BLCc via a coupling circuit CPc having transistors 104c, 105c.

In the memory cell array 10, the sense amplifiers SA, SAb, SAc of adjacent bit line pairs are each arranged such that they are offset with respect to one another. The method of operation of the precharge circuits PR, PRb, PRc shall be explained using the example of the precharge circuit PR. A potential can be supplied to the bit lines BL1, BLC via the potential input LIM. This usually results as a mean value of a high bit line potential and a low bit line potential, which can be provided by the sense amplifier SA. A control signal at the control input EQL can be used to turn on the transistors 100, 101, 102 in order, on the one hand, to thus connect the bit lines BL1 and BLC in a low-impedance manner and, on the other hand, to supply the potential at the potential input LIM to the bit line BL1, BLC. The potential input LIM is usually connected to a voltage source, which is not shown here and is intended to provide the precharge potential, in a high-impedance manner.

A connection between the bit line BL1, BLC and the sense amplifier SA can be established or interrupted using the transistors 104, 105. This makes it possible to also connect the sense amplifier SA to a further bit line pair (not shown here). In this case, however, only one bit line pair should ever be simultaneously conductively connected to the sense amplifier SA. The bit lines BL1, BLC are connected to the sense amplifier SA on the basis of a signal at the selection input MUX.

The transistors 104b, 105b at the sense amplifier SAb and the transistors 104c, 105c at the sense amplifier SAc perform the same function which has been described. Further bit line pairs can thus also be respectively connected to the sense amplifiers SAb and SAc. Driving is effected independently via the selection inputs MUX, MUXb, MUXc.

The design and function of the precharge circuits PRb and PRc correspond to those of the precharge circuit PR. The precharge circuits PR, PRb, PRc are driven independently via the control inputs EQL, EQLb, EQLc.

In order to test the semiconductor memory, the transistors in the precharge circuits PR, PRb, PRc, for example, are turned on using control signals at the control inputs EQL, EQLb, EQLc. As a result, the precharge potential at the potential input LIM is supplied to the bit line pairs BL1, BLC, BL1b, BLCb and BL1c, BLCc. When all of the bit lines have been precharged to the precharge potential at the potential input LIM, the transistors in the precharge circuits PR, PRb and PRc can be turned off again. Applying a control voltage to the word line WL drives the memory cells MC, MCb, MCc and conductively connects them to the respective first bit lines BL1, BL1b, BL1c. This results in a respective small potential difference on the first bit lines BL1, BL1b, BL1c with respect to the potential on the second bit lines BLC, BLCb, BLCc.

The transistors 104, 105, 104b, 105b, 104c, 105c are turned on, with the result that the sense amplifiers SA, SAb, SAc are each connected to the bit lines in a low-impedance manner. The sense amplifiers SA, SAb, SAc detect and amplify the potential difference on the bit lines. If the potential difference is positive, the high bit line potential is respectively applied to the first bit line BL1, BL1b, BL1c, while the low bit line potential is applied to the second bit line BLC, BLCb, BLCc. If the potential difference is negative, the low bit line potential is applied to the first bit line BL1, BL1b, BL1c and the high bit line potential is applied to the second bit line BLC, BLCb, BLCc. This is also called spreading of the bit lines.

Driving the transistors in the precharge circuits PR, PRb, PRc for an on state connects the first bit lines BL1, BL1b, BL1c to the respective second bit lines BLC, BLCb, BLCc in a low-impedance manner. This results in a current flowing from the sense amplifiers SA, SAb, SAc over the bit lines BL1, BLC, BL1b, BLCb, BL1c, BLCc via the transistors 100, 100b, 100c. If the transistors 101 and 102 are essentially identical, a potential which essentially corresponds to the mean value of the low bit line potential and the high bit line potential will be established at the node of the transistors 101, 102. Since this potential is usually also supplied as a precharge potential via the potential input, the current flow via the transistors 101, 102 is negligible. A similar situation applies to the transistors 101b, 102b and the transistors 101c, 102c.

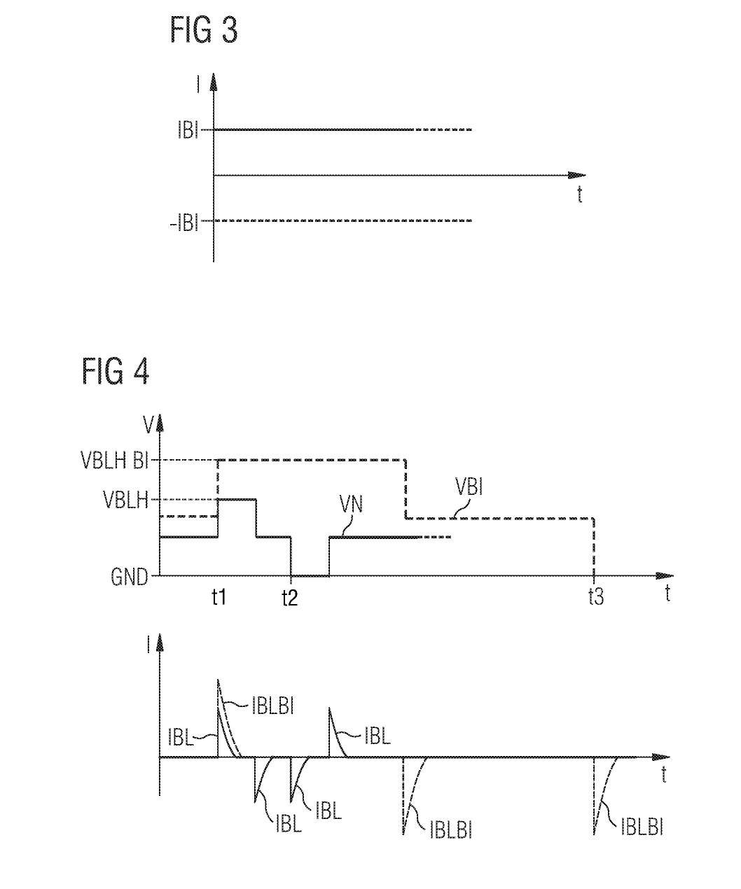

The resultant current flow is a static current whose temporal profile is illustrated by way of example in FIG. 3. In the case of a positive potential difference between the potentials of the bit lines, a positive current with the value IBI is produced, for example. In contrast, in the case of a negative potential difference, a negative current with the value -IBI is produced, the negative mathematical sign expressing the changed polarity of the direction of current flow.

As a result of the static current, the bit lines can be loaded in a more efficient manner than with dynamic charge reversal currents in the case of other embodiments of integrated semiconductor memories. In the case of such semiconductor memories, loading with a static current is additionally impossible since the memory cells MC, MCb, MCc are not connected to the first bit line BL1, BL1b, BL1c between the sense amplifier SA, SAb, SAc and the precharge circuit PR, PRb, PRc, as is also shown in FIG. 2. In the case of such a semiconductor memory, the precharge circuits PR, PRb, PRc are connected to the bit lines BL1, BLC, BL1b, BLCb, BL1c, BLCc on the side of the sense amplifier SA, SAb, SAc. As a result, current flow over the entire bit line is not possible.

The sense amplifier and the precharge circuit are essentially arranged in the described integrated semiconductor memory in an area-neutral manner since only the precharge circuit at the other end of a bit line pair needs to be shifted.

In other embodiments of semiconductor memories, the transistors in a precharge circuit are only ever switched to low impedance when no word line is activated and so that the sense amplifiers which are connected to the corresponding bit line pair do not amplify a potential difference. In the embodiments described, this locking can be canceled in order to enable the static current flow. This can be effected, for example, using the control circuit CC shown in FIG. 1.

After the bit lines have been loaded with the static current, the functionality of the bit lines can be checked by means of write and read access, as is also carried out during conventional operation of the semiconductor memory. A defective bit line which was destroyed by the current loading cannot be identified as being operational during this write and read access.

If a plurality of bit line pairs are simultaneously subjected to current loading, the time needed to test the entire semiconductor memory is reduced. As a result, the semiconductor memory can be tested in an even more efficient manner. The exemplary embodiments are illustrated, by way of example, for one bit line pair in FIG. 1 and for three bit line pairs in FIG. 2. However, the principle can be applied to any desired number of bit line pairs and thus to all bit line pairs required in an integrated semiconductor memory.

If a plurality of bit line pairs are simultaneously subjected to current loading, the number of bit line pairs is essentially limited only by the capacity of the current and voltage supply.

In one of the embodiments shown, the integrated semiconductor memory can be used in a dynamic semiconductor memory module, for example, a DRAM memory module.

In one embodiment of a method for testing an integrated semiconductor memory, a first bit line having a first end and a second end and a second bit line having a first end and a second end are provided. In addition, a plurality of memory cells which are connected to the first bit line between the first and second ends of the first bit line are provided. A precharge potential is fed to the first and second bit lines. One of the plurality of memory cells is driven in such a manner that a potential difference between a potential on the first bit line and a potential on the second bit line is produced. This potential difference is amplified on the first and second bit lines using a voltage generation circuit which is connected to the first end of the first bit line and to the first end of the second bit line. In this case, while the potential difference is being amplified, the first and second bit lines are connected at the second end of the first bit line and at the second end of the second bit line in a low-impedance manner in such a manner that a current flows over the first and second bit lines as a result of the amplified potential difference. Write and read access to at least one of the plurality of memory cells is performed.

As a result of the precharge potential being fed to the first and second bit lines, the latter have essentially the same potential. Driving one of the plurality of memory cells results in a change in potential on the first bit line, thus resulting in a potential difference between the potentials of the two bit lines. This potential difference is amplified using a voltage generation circuit. Connecting the two bit lines in a low-impedance manner results in a static current flow on account of the electrical resistance of the bit lines. In this case, the current flows over the entire area of the bit lines which is used during operation. The current flow physically loads or stresses the bit lines, with the result that bit lines that are susceptible to faults or bit lines having defective bit line sections are caused to fail with an increased degree of probability.

Subsequently performing write and read access, also takes place during normal operation of the semiconductor memory, makes it possible to determine whether the bit lines are still intact after loading. This is because error-free reading is possible only with bit lines which have not been damaged. A fault during reading indicates damage to the bit line pair. The memory cell which is used to carry out the read process need not be the same memory cell which was driven in order to generate the current flow.

In another embodiment of the method, a first data item is applied to a data connection when performing the write and read access. The applied data item is read into the at least one of the plurality of memory cells. Reading a storage state of the at least one of the plurality of memory cells generates a second data word at the data connection. The second data item is compared with the applied first data item. When the two data items differ, it can be assumed that one of the bit lines is damaged.

In one embodiment of the method, the low-impedance connection is effected by turning on a first controllable switch on the basis of a control signal at a control input. The precharge potential can be fed in by turning on a second controllable switch and a third controllable switch. In this case, the second controllable switch couples the second end of the first bit line to a supply connection for supplying the precharge potential and the third controllable switch couples the second end of the second bit line to the supply connection. Control connections of the second and third controllable switches are coupled to the control input in this case.

If the two controllable switches are turned on, essentially the same potential can be established on the two bit lines by applying the precharge potential to a connecting node of the two switches. A potential which results from a mean value of a high bit line voltage and a low bit line voltage is usually selected for this purpose. Such a potential may also be referred to as a center potential.

The potential difference which is produced when driving a memory cell is usually amplified in such a manner that the voltage generation circuit generates a first line potential on the first bit line and a second line potential on the second bit line. To this end, the high bit line voltage is applied to one of the bit lines and the low bit line voltage is applied to the other bit line. The process of amplifying the potential difference is also referred to as spreading of the bit lines. As a result of the precharge potential being fed to the bit lines, spreading proceeds from a defined starting potential.

In another embodiment of the method, a storage state which is stored in the memory cell is read when the one memory cell of the plurality of memory cells is being driven. For this purpose, before the one memory cell is driven, a desired storage state can be stored in the memory cell. When the memory cell is being driven, the storage state stored in the memory cell, for example, in the form of an electrical charge, is used to influence the potential on the first bit line.

The contents of the memory cell are used to determine whether a positive or a negative potential difference between the potentials of the bit lines will be produced. A polarity of the potential difference thus depends on the stored storage state of the one memory cell. The direction of the static current is also determined by the latter. Storing a desired storage state in the memory cell before the latter is driven thus makes it possible to determine the direction of the static current flow in a defined manner in advance.

What is claimed is:

1. An integrated semiconductor memory with a test function, the semiconductor memory comprising:
a first bit line having a first end and a second end;
a second bit line having a first end and a second end;
a voltage generation circuit having a first connection, at which a first line potential can be generated and that is coupled to the first end of the first bit line, and a second connection, at which a second line potential can be generated and that is coupled to the first end of the second bit line;
a plurality of memory cells coupled to the first bit line between the first and second ends of the first bit line; and
a circuit unit having a control input for supplying a first control signal and a first controllable switch coupled between the second end of the first bit line and the second end of the second bit line and whose control connection is coupled to the control input.

2. The integrated semiconductor memory as claimed in claim 1, wherein the control circuit has an input for selecting a first operating mode or a second operating mode of the integrated semiconductor memory;
the first line potential being generated on the first bit line and the second line potential being generated on the second bit line in the first and second operating modes when reading one of the plurality of memory cells; and
the control circuit turning off the first switch in the first operating mode and turning it on in the second operating mode.

3. The integrated semiconductor memory as claimed in claim 1, further comprising a coupling circuit coupled between the first ends of the first bit line and second bit line and the connections of the voltage generation circuit, the coupling circuit having a selection input designed to couple the first ends of the first bit line and second bit line to the connections of the voltage generation circuit on the basis of a second control signal at the selection input.

4. The integrated semiconductor memory as claimed in claim 3, wherein the coupling circuit comprises a first controllable switch and a second controllable switch:
the first controllable switch being coupled between the first connection of the voltage generation circuit and the first end of the first bit line;
the second controllable switch being coupled between the second connection of the voltage generation circuit and the first end of the second bit line; and
control connections of the controllable switches being coupled to the selection input.

5. The integrated semiconductor memory as claimed in claim 1, wherein a circuit unit is in the form of a precharge circuit for feeding a precharge potential to the first bit line and second bit line, the precharge potential being between the first line potential and second line potential.

6. The integrated semiconductor memory as claimed in claim 5, wherein the precharge circuit comprises:
a second controllable switch that couples the second end of the first bit line to a supply connection for supplying the precharge potential; and
a third controllable switch that couples the second end of the second bit line to the supply connection;
wherein control connections of the second and third controllable switches are coupled to the control input.

7. The integrated semiconductor memory as claimed in claim 1, wherein each controllable switch comprises a transistor.

8. The integrated semiconductor memory as claimed in claim 1, wherein at least one of the plurality of memory cells is designed to generate a potential difference between a potential on the first bit line and a potential on the second bit line when driven using a word line.

9. The integrated semiconductor memory as claimed in claim 8, wherein the voltage generation circuit is designed to amplify the potential difference.

10. The integrated semiconductor memory as claimed in claim 9, wherein the voltage generation circuit comprises a sense amplifier, the sense amplifier generating the first line potential and second line potential on the first bit line and second bit line on the basis of the potential difference in order to amplify the potential difference.

11. The integrated semiconductor memory as claimed in claim 1, wherein the voltage generation circuit is designed to generate a third line potential at the first connection and a fourth line potential at the second connection, a potential difference between the third and fourth line potentials being greater than a potential difference between the first line potential and second line potential.

12. A dynamic semiconductor memory having an integrated semiconductor memory with a test function, the semiconductor memory comprising:
a first bit line having a first end and a second end;
a second bit line having a first end and a second end;
a voltage generation circuit having a first connection, at which a first line potential can be generated and which is coupled to the first end of the first bit line, and a second connection, at which a second line potential can be generated and which is coupled to the first end of the second bit line;
a plurality of memory cells coupled to the first bit line between the first end and second end of the first bit line; and
a circuit unit having a control input for supplying a first control signal and a first controllable switch that is coupled between the second end of the first bit line and the second end of the second bit line and whose control connection is coupled to the control input.

13. A method for testing an integrated semiconductor memory, the method comprising:
providing a first bit line having a first end and a second end and a second bit line having a first end and a second end;
providing a plurality of memory cells coupled to the first bit line between the first and second ends of the first bit line;
feeding a precharge potential to the first and second bit lines;
driving one of the plurality of memory cells in such a manner that a potential difference between a potential on the first bit line and a potential on the second bit line is produced;
amplifying the potential difference on the first bit line and second bit line using a voltage generation circuit that is coupled to the first end of the first bit line and to the first end of the second bit line, such that, while the potential difference is being amplified, the first bit line and second bit line are coupled at the second end of the first bit line and at the second end of the second bit line in a low-impedance manner in such a manner that a current flows between the first bit line and second bit line; and
accessing at least one of the plurality of memory cells.

14. The method as claimed in claim 13, wherein accessing at least one of the plurality of memory cells comprises:
applying a first data item to a data connection;
reading the applied data item into the at least one of the plurality of memory cells;
generating a second data item at the data connection by reading a storage state of the at least one of the plurality of memory cells; and
comparing the first data item with the second data item.

15. The method as claimed in claim 13, wherein the low-impedance connection is effected by turning on a first controllable switch on the basis of a control signal at a control input.

16. The method as claimed in claim 15, wherein:
the precharge potential is fed in by turning on a second controllable switch and a third controllable switch;
the second controllable switch couples the second end of the first bit line to a supply connection for supplying the precharge potential;
the third controllable switch couples the second end of the second bit line to the supply connection; and
control connections of the second and third controllable switches are coupled to the control input.

17. The method as claimed in claim 13, wherein a first line potential is generated on the first bit line and a second line potential is generated on the second bit line when the voltage generation circuit is amplifying the potential difference.

18. The method as claimed in claim 13, wherein a storage state that is stored in the memory cell is read when one memory cell of the plurality of memory cells is being driven.

19. The method as claimed in claim 18, wherein a polarity of the potential difference depends on the stored storage state of the one memory cell.

20. The method as claimed in claim 13, wherein before the one memory cell of the plurality of memory cells is driven, a desired storage state is stored in the memory cell.

21. An integrated semiconductor memory with a test function, said semiconductor memory comprising:
a bit line pair having a first end and a second end;
a voltage generation circuit having a first connection and a second connection that are coupled to the first end of the bit line pair, wherein a first line potential can be generated at the first connection and a second line potential can be generated at the second connection;
a plurality of memory cells coupled to a first bit line of the bit line pair between the first and second ends of the bit line pair; and
a switch coupled between the second end of the bit line pair, the switch being controlled on the basis of a first control signal.

22. The integrated semiconductor memory as claimed in claim 21, further comprising:
a control circuit having an input for selecting a first operating mode or a second operating mode of the integrated semiconductor memory;
the first line potential being generated on the first bit line and the second line potential being generated on a second bit line of the bit line pair when reading one of the plurality of memory cells in the first and second operating modes; and
the control circuit turning off the switch in the first operating mode and turning it on in the second operating mode.

23. The integrated semiconductor memory as claimed in claim 21, wherein the first end of the bit line pair and the connections of the voltage generation circuit are coupled using a coupling circuit, and the coupling circuit is designed to couple the first end of the bit line pair to the connections of the voltage generation circuit on the basis of a second control signal.

24. The integrated semiconductor memory as claimed in claim 23, wherein the voltage generation circuit comprises a sense amplifier that is designed to amplify a potential difference on the bit line pair, the potential difference being generated by one of the plurality of memory cells.

25. A method for testing an integrated semiconductor memory, the method comprising:
feeding a precharge potential to a bit line pair;
driving one of a plurality of memory cells, that are coupled to a first bit line of the bit line pair between a first end and a second end of the bit line pair, the driving producing a potential difference on the bit line pair;
amplifying the potential difference at the first end of the bit line pair, such that, while the potential difference is being amplified, the second end of the bit line pair is coupled in a low-impedance manner in such a manner that a current flows over the bit line pair; and
accessing at least one of the plurality of memory cells.

26. The method as claimed in claim 25, wherein accessing at least one of the memory cells comprises:
reading a first data item into the at least one of the plurality of memory cells;
generating a second data item by reading a storage state of the at least one of the plurality of memory cells; and
comparing the first data item with the second data item.

27. The method as claimed in claim 25, wherein a first line potential is generated on the first bit line and a second line potential is generated on a second bit line of the bit line pair when amplifying the potential difference.

28. The method as claimed in claim 25, wherein a storage state that is stored in the memory cell is read when the one memory cell of the plurality of memory cells is being driven.

29. The method as claimed in claim 28, wherein a polarity of the potential difference depends on the stored storage state of the one memory cell.
